(19) United States
(12) Patent Application Publication
(10) Pub. No.: US 2003/0183337 A1
(43) Pub. Date: Oct. 2, 2003

(54) Apparatus and method for use of optical diagnostic system with a plasma processing system

(76) Inventors: James Fordemwalt, Chandler, AZ (US); Audunn Ludviksson, Scottsdale, AZ (US); Andrej Mitrovic, Phoenix, AZ (US); Norman Wodecki, Phoenix, AZ (US)

Correspondence Address: PILLSBURY WINTHROP, LLP, P.O. BOX 10500, MCLEAN, VA, 22102, US

(21) Appl. No.: 10/388,540

(22) Filed: Mar. 17, 2003

Related U.S. Application Data
(60) Provisional application No. 60/367,716, filed on Mar. 28, 2002.

(51) Int. Cl. H05H 1/24; C23C 16/00; H01L 21/306

(52) U.S. Cl. 156/345.24; 427/569; 118/663; 118/712; 118/713; 118/715; 118/723 E; 118/723 I; 156/345.26; 156/345.43; 156/345.47; 156/345.48

(57) ABSTRACT

A plasma processing system and method for operating a windowless optical diagnostic system in conjunction with a plasma processing system. The plasma processing system comprises a windowless optical diagnostic system that is constructed and arranged to detect a plasma process condition. The method includes providing a first pressure within a chamber of the plasma processing system and providing a second pressure within a windowless optical diagnostic chamber in which the windowless optical diagnostic system is positioned. The method further includes controlling the second pressure within the windowless optical diagnostic chamber relative to the first pressure within the chamber and optically detecting a plasma process condition.

This application derives the benefit of U.S. Provisional application 60/367,716, filed Mar. 28, 2002, the contents of which are incorporated herein by reference.

### BACKGROUND OF THE INVENTION

1. Field of Invention

The present invention relates to plasma processing and more particularly to monitoring of the plasma processing using an optical diagnostic system.

2. Description of Background Information

Typically, plasma is a collection of gaseous species, some of which are charged. Plasmas are useful in certain processing systems for a wide variety of applications. For example, plasma processing systems are of considerable use in material processing and in the manufacture and processing of semiconductors, integrated circuits, displays and other electronic devices, both for etching and layer deposition on substrates, such as, for example, semiconductor wafers.

Optical diagnostic methods are widely used to monitor plasma processes and to determine an end point of a plasma process, for example, a plasma etching process.

Generally, conventional optical diagnostic methods use a light transmissive window to separate the plasma process chamber from the optical detection system, as the plasma process chamber must operate at low vacuum, typically a few milliTorr to a few Torr. The window tends to become coated with etch by-products that cloud the window. Although this method is widely used and has been quite successful, it is problematic when the window becomes clouded because the optical diagnostic data can be skewed and even could be rendered invalid. In addition, the window would need to be cleaned or else replaced before more product could be processed, either being an expensive and time consuming operation.

Accordingly, it would be desirable to remove the need for a window or a viewport for optical diagnostic methods and systems used in conventional plasma processing.

### SUMMARY OF THE INVENTION

One aspect of the invention is to provide a plasma processing system in communication with a windowless optical diagnostic system. The plasma processing system comprising a chamber containing a plasma processing region, a chuck constructed and arranged to support a substrate within the chamber in the processing region and a chamber opening to enable plasma within the plasma processing region to exit the chamber. A plasma generator is positioned in communication with the chamber and is constructed and arranged to generate a plasma during a plasma process in the plasma processing region. A windowless optical diagnostic system is positioned in communication with the chamber opening and is constructed and arranged to detect a plasma process condition.

Another aspect of the invention is to provide a method for operating an optical diagnostic system in communication with a plasma processing system. The plasma processing system has a chamber containing a plasma processing region in which a plasma can be generated during a plasma process and the windowless optical diagnostic system is positioned in a windowless optical diagnostic chamber. The method comprises providing a first pressure within the chamber and providing a second pressure within the windowless optical diagnostic chamber. The second pressure within the windowless optical diagnostic chamber is controlled relative to the first pressure within the chamber to reduce contamination of the windowless optical diagnostic system. Thus, a method can be provided without the need for a window between the optical diagnostic system and the plasma processing system.

These and other aspects will be achieved by the invention wherein the need for the window between the plasma processing chamber and the optical diagnostic system is removed. Further, these and other aspects and features of the invention will become apparent from the following detailed description considered in conjunction with the accompanying drawings. It is to be understood, however, that the drawings are for the purpose of illustration only, and not as a definition of the limits or principles of the invention.

### BRIEF DESCRIPTION OF THE DRAWINGS

The accompanying drawings, which are incorporated in and constitute a part of the specification, embodiments of the invention, and together with the general description given above and the detailed description of the embodiments given below, serve to explain the principles of the invention wherein:

FIG. 1 is a diagrammatic cross section of an embodiment of a plasma processing system in accordance with principles of the invention, showing a plasma processing chamber in communication with a windowless optical diagnostic system;

FIG. 2 is a diagrammatic cross section of another embodiment of a plasma processing system, showing a plasma processing chamber in communication with a windowless optical diagnostic system;

FIG. 3 is a diagrammatic cross section of yet another embodiment of a plasma processing system, showing a plasma process chamber in communication with the windowless optical diagnostic system;

FIG. 4 is a flow chart for the operation of a plasma processing system; and

FIG. 5 is a flow chart showing a method of operating a windowless optical diagnostic system in communication with a plasma processing system in accordance with principles of the invention.

### DETAILED DESCRIPTION OF EMBODIMENTS

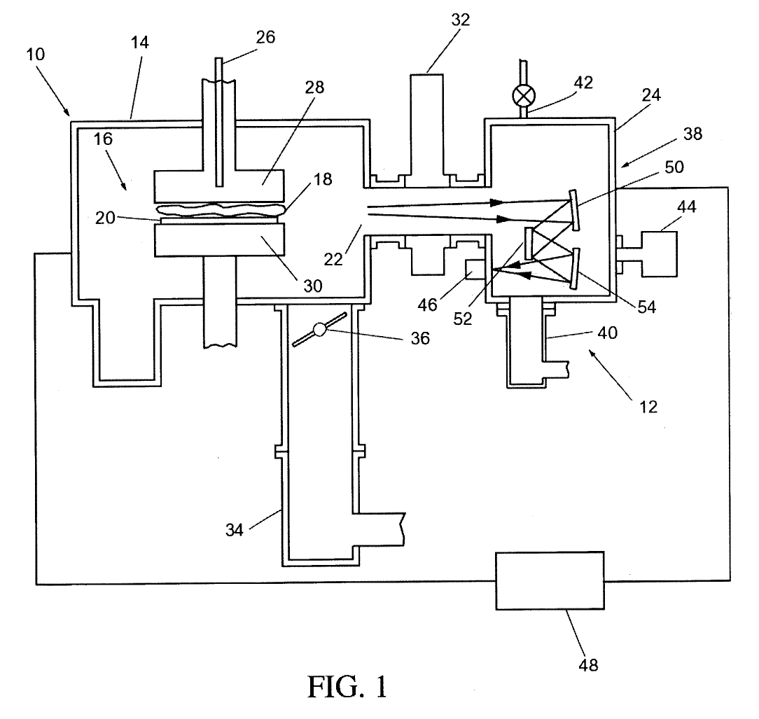

FIG. 1 shows an embodiment of a plasma processing system according to principles of the invention. The plasma processing system, generally indicated at 10, is in communication with a windowless optical diagnostic system, generally indicated at 12.

The plasma processing system 10 comprises a plasma process chamber, generally indicated at 14, that defines a plasma processing region 16 in which a plasma 18 can be generated. A chuck or electrode 30 can be positioned in the chamber 14 and is constructed and arranged to support a substrate 20, which may be a semiconductor wafer, for example, within the chamber 14 in the processing region 16. The substrate 20 can be a semiconductor wafer, integrated circuit, a sheet of a polymer material to be coated, a metal to be surface hardened by ion implantation, or some other semiconductor material to be etched or deposited, for example.

Although not shown, coolant can be supplied to the chuck 30, for example, through cooling supply passages coupled to the chamber 14. Each cooling supply passage can be coupled to a cooling supply source. For example, the cooling supply passages could be individually connected to the cooling supply source. Alternatively, cooling supply passages could be interconnected by a network of interconnecting passages, which connect all cooling supply passages in some pattern.

Generally, plasma generation gas, which can be any gas that is ionizable to produce a plasma, is introduced into the chamber 14 to be made into a plasma, for example, through a gas inlet 26. The plasma generation gas can be selected according to the desired application as understood by one skilled in the art and can be nitrogen, xenon, argon, carbon tetrafluoride (CF₄) or octafluorocyclobutane (C₄F₈) for fluorocarbon chemistries, chlorine (Cl₂), hydrogen bromide (HBr), or oxygen (O₂), for example.

The gas inlet 26 is coupled to the chamber 14 and is configured to introduce plasma processing gases into the plasma processing region 16. A plasma generator in the form of upper electrode 28 and lower electrode 30 may be coupled to the chamber 14 to generate the plasma 18 within the plasma processing region 16 by ionizing the plasma processing gases. The plasma processing gases can be ionized by supplying RF and/or DC power thereto, for example. In some applications, the plasma generator may be an antenna or RF coil capable of supplying RF power, for example.

A variety of gas inlets or injectors and various gas injecting operations can be used to introduce plasma processing gases into the plasma processing chamber 14, which can be hermetically sealed and can be formed from aluminum or another suitable material. The plasma processing gases are often introduced from gas injectors or inlets located adjacent to or opposite from the substrate. For example, as shown in FIG. 1, gases supplied through the gas inlet 26 can be injected through an inject electrode (upper electrode 28) opposite the substrate in a capacitively coupled plasma (CCP) source. The power supplied to the plasma can ignite a discharge with the plasma generation gas introduced into the chamber 14, thus generating a plasma, such as plasma 18.

Alternatively, in embodiments not shown, the gases can be injected through a dielectric window opposite the substrate in a transformer coupled plasma (TCP) source. Other gas injector arrangements are known to those skilled in the art and can be employed in conjunction with the plasma processing chamber 14.

The plasma process chamber 14 is fitted with an outlet having a first vacuum pump 34 and a valve 36, such as a throttle control valve, to provide gas pressure control in the plasma process chamber 14.

Various leads (not shown), for example, voltage probes or other sensors, can be coupled to the plasma processing system 10.

An opening 22 extends radially from the process chamber 14 to a vacuum tight chamber 24 of the windowless optical diagnostic system 12. The vacuum tight chamber 24 can be formed in communication with the process chamber 14 to enable optical transmission, such as light transmission, from the plasma 18 to the windowless optical diagnostic system 12, as will be described in further detail below.

A gate valve 32 is fastened to the plasma process chamber 14, adjacent to the chamber opening 22. The gate valve 32 is provided to allow isolation of the optical diagnostic system chamber 24 from the plasma processing chamber 14 for maintenance operations, such as cleaning, or periods of gas purge, for example. The gate valve 32 is not essential to the invention and may be omitted in an alternative embodiment.

The windowless optical diagnostic system 12 is constructed and arranged to monitor plasma processes. This includes detecting an endpoint of a plasma process occurring in the chamber 14. The windowless optical diagnostic system 12 comprises a monochromator 38, which is configured to receive optical transmission from the plasma 18, and a detector system 46 associated with the monochromator 38. The detector system 46 is configured to detect a plasma process condition based on the optical transmission from the plasma 18. The detector system 46 could use a photomultiplier tube, a CCD or other solid state detector to at least partially detect the plasma process condition, such as an endpoint of a plasma process, for example.

The monochromator 38 of the optical diagnostic system may rely on a Czerny-Turner configuration (shown in FIG. 1), a Fabry-Perot interferometer, a Michelson interferometer, or other optics to operate. However, other optical devices capable of analyzing an optical spectrum, e.g., separating light into wavelengths, may be used as well. Any optical detection device employing any sort of optics may be substituted for the monochromator 38. The monochromator 38 may, for example, employ apertures, mirrors and grating optics.

For example, as shown in FIGS. 1-3, the Czerny-Turner type monochromator uses a first concave mirror 50 to collimate light passing into the monochromator 38. The first mirror 50 reflects light onto a diffraction grating 52, which in turn directs wavelength selected light onto a second concave mirror 54. The second mirror 54 reflects and focuses the wavelength selected light onto the detector 46. Slits or apertures (not shown) could be located in front of the first mirror 50 (between the chamber opening 22 and the first mirror 50) and between the second mirror 54 and the detector 46. The detector 46 receives the wavelength selected light and turns the light into an electronic signal that is read by a controller 48. A wavelength scan (spectrum) could be performed by rotating the grating 52 about a central axis thereof, for example.

The monochromator 38 can be positioned within the windowless optical diagnostic system 12 to be fitted with the vacuum tight chamber 24. A second vacuum pump 40 is positioned in communication with the chamber 24, and together with a gas inlet 42 and a capacitance manometer 44, a pressure in the optical diagnostic system chamber 24 can be maintained at or slightly above a pressure in the plasma processing chamber 1. The chamber opening 22 between the plasma processing chamber 14 and the monochromator 38 is kept as small as is compatible with the opening necessary for the transmission of light from the plasma 18 into the monochromator 38. As a result, the diffusion of plasma byproducts into the monochromator 38, which could result in fouling of the optics of the monochromator 38, is minimized.

The controller 48 is capable of generating control voltages sufficient to communicate and activate inputs to plasma processing system 10 as well as monitor outputs from plasma processing system 10. For example, the controller 48 can be coupled to and can exchange information with the upper electrode 28, the lower electrode 30 and the gas inlet 26. A program, which can be stored in a memory, may be utilized to control the aforementioned components of plasma processing system 10 according to a stored process recipe. Furthermore, controller 48 is capable of controlling the components of the optical diagnostic system 12. For example, the controller 48 can be configured to control one or more of the capacitance manometer 44, the gas inlet 42, the gate valve 32, the vacuum manifold 102, the differential pumping manifold 202, the valves 210, 212, the vacuum pump 214, and the detector 46. Alternatively, multiple controllers 48 could be provided, each of which being configured to control different components of either the plasma processing system 10 or the optical diagnostic system 12, for example. One example of the controller 48 is a digital signal processor (DSP), Model TSM320 Family available from Texas Instruments, Dallas, Tex.

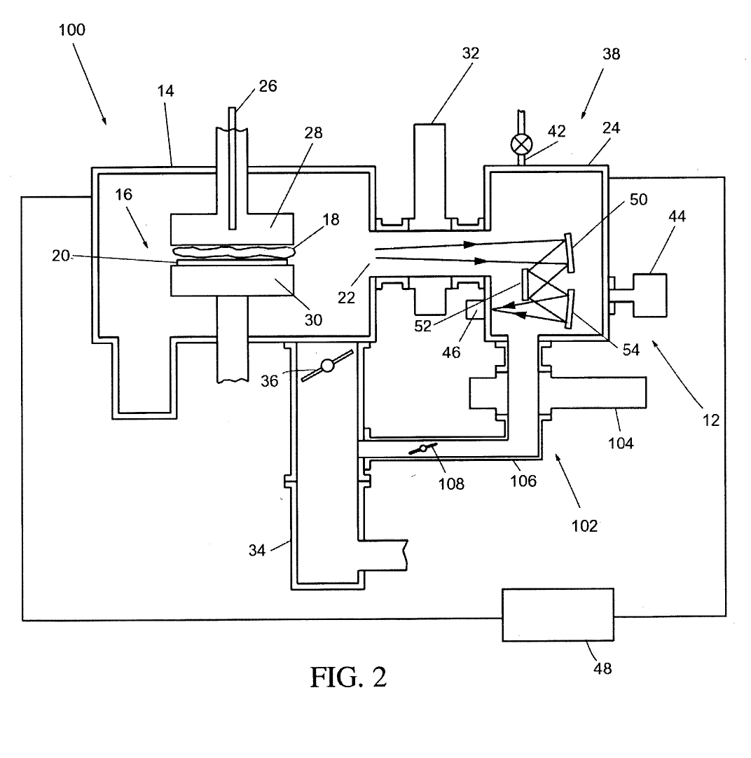

Alternate configurations of the plasma processing system 10 are possible. For example, another embodiment of the plasma processing system 10 will be described below. In the description of this embodiment, only the points of difference of the embodiment from the previous embodiment will be described. That is, in the alternative embodiment shown in FIG. 2, the constituent parts the same as those in the first embodiment are referenced correspondingly in the drawings and the description about them will be omitted.

A plasma processing system 100 is shown in FIG. 2. The plasma processing system 100 includes a vacuum manifold 102 comprising a gate valve 104, a vacuum line 106 which connects the optical diagnostic system chamber 24 to the first vacuum pump 34, and a throttle valve 108. The gate valve 104, the vacuum line 106 and the throttle valve 108, together with the gas inlet 42 and the capacitance manometer 44 described above, permit independent control of the pressure in the optical diagnostic system chamber 24.

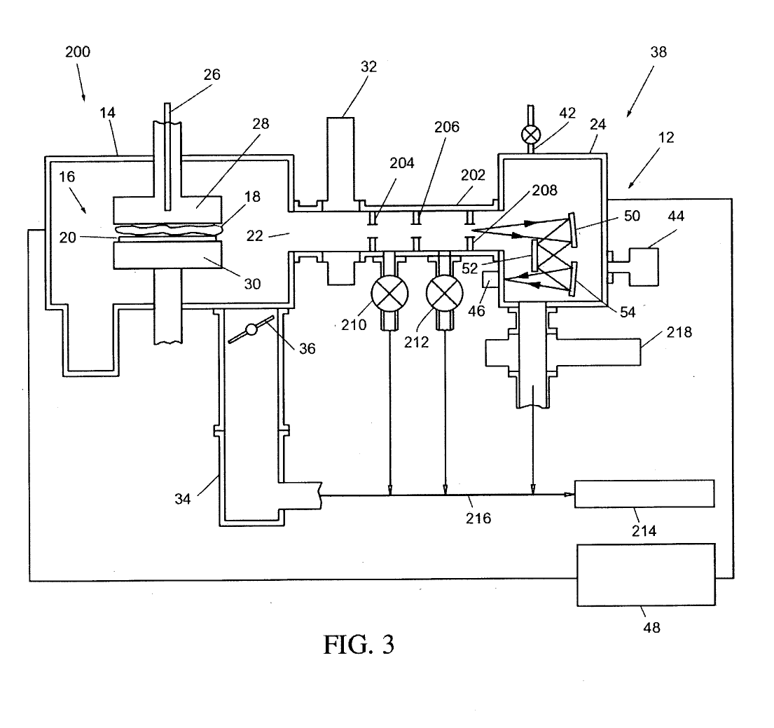

Another embodiment of the plasma processing system 100 will be described below. In the description of this embodiment, only the points of difference of the embodiment from the previous embodiment will be described. That is, in the alternative embodiment shown in FIG. 3, the constituent parts the same as those in the first embodiment are referenced correspondingly in the drawings and the description about them will be omitted.

FIG.3 shows a plasma processing, system 200, which is yet another embodiment of the plasma processing system 100. The plasma processing system 200 uses differential pumping through the chamber opening 22 to reduce the byproducts of the plasma process that diffuse into the monochromator 38. The plasma processing system 200 comprises a differential pumping manifold 202 that enables the differential pumping to occur. The monochromator 38 is attached to the plasma process chamber 14 by the differential pumping manifold 202, and a gate valve 32. The differential pumping manifold 202 comprises a plurality of apertures 204, 206, 208 in communication with pumping lines having a plurality of valves 210, 212 positioned therein. The pumping lines communicate with a main vacuum pump 214 through a vacuum manifold 216. The vacuum pump 214 may be a mechanical vacuum pump, a turbomolecular pump or any other suitable type of vacuum pump. Chamber 24 is evacuated through a gate valve 218 by vacuum pump 214.

The plasma processing system 200 permits the monochromator 38 to be operated at a significantly higher pressure than the plasma process chamber 14 due to the differential pumping. As a result, the probability of byproducts of the plasma process diffusing through the apertures 204, 206, 208 into the monochromator 38 is reduced. Thus, the probability of the optics being clouded by the plasma byproducts is also reduced.

The plurality of valves 210, 212 of the plasma processing system 200 can also permit the monochromator 38 to be operated at a significantly lower pressure than the plasma process chamber 14. For example, in another embodiment of the plasma processing system (not shown), the embodiment in FIG. 3 is modified so that pumping lines from valves 210, 212 and from the gate valve 218 are connected with a vacuum pump (not shown). The vacuum pump would communicate with the main vacuum pump 214 through the vacuum manifold 216. This configuration would allow the monochromator 38 to be operated at a significantly lower pressure than the plasma process chamber 14.

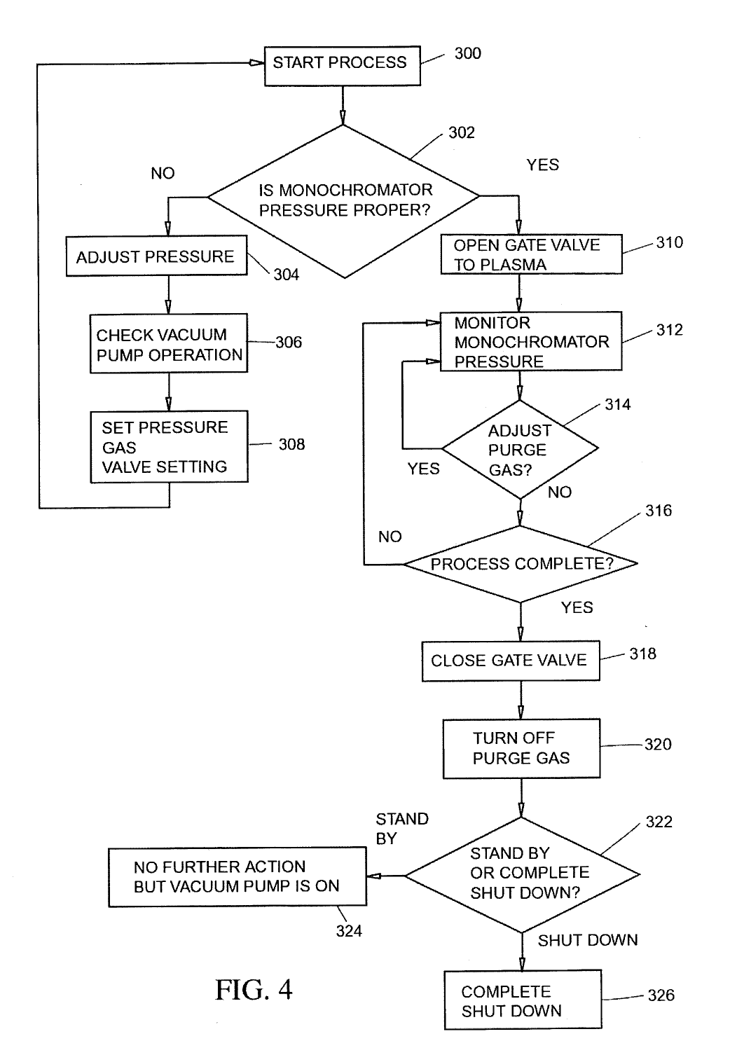

FIG. 4 shows a flow diagram that illustrates the operation of the plasma processing system 10, which is described above with reference to FIG. 1. The system 10 could be used when monitoring a plasma process such as a plasma etching to detect an endpoint of the plasma process, for example.

At 300, the plasma process begins. At 302, a determination is made whether the pressure in the optical diagnostic system chamber 24 is proper or desired. If not, then a command to adjust the pressure in the optical diagnostic system chamber 24 to an appropriate level is given at 304. At 306, an operation of the vacuum pump 40 is checked. At 308, a setting of the inlet gas valve 42 is checked for properness and set to the proper setting, if necessary. The process then starts again at 300, and again the pressure within the optical diagnostic system chamber 24 is checked at 302.

If the pressure in the optical diagnostic system chamber 24 is correct, then the gate valve 32 is opened at 310. At 312, the system 10 continues to monitor the pressure in the optical diagnostic system chamber 24 and at 314, adjust the flow of inlet gas 42, as necessary. At 316, a determination is made whether the process is complete. If not, the system 10 continues to monitor the pressure in the optical diagnostic system chamber 24, to adjust the flow of inlet gas 42, as necessary, and to determine whether the process is complete. If the process is complete, a command to close the gate valve 32 is given at 318, along with a command to close the inlet gas valve 42 at 320. At 322, a determination is made whether the system is to be put on stand-by or to be completely shut down. If the system is to put on standby, as shown at 324, no further action is taken. However, if the system is to be completely shut down, appropriate action is taken at 326.

While a flow diagram is not provided for the plasma processing systems 100 and 200, the operation of the plasma processing systems 100 and 200 operate in a similar manner as the plasma processing system 10, as described above with reference to FIG. 4. For example, in the plasma processing system 100, the gate valve 104, the vacuum line 106 and the throttle valve 108, together with the gas inlet 42 and the capacitance manometer 44 described above, permit independent control of the pressure in the optical diagnostic system chamber 24. The gate valve 104 and the throttle valve 108 are commanded for pressure adjustment along with the gas flow control 42 and the gate valve 104 and an appropriate pressure is set or determined.

In the plasma processing system 200, for example, the chamber 24 is pumped down, the gate valve 218 is closed, and a purge gas is admitted through the gas inlet 42. The valves 210, 212 are opened and the pressure in the optical diagnostic system chamber 24 is controlled by the gas flow through the gas inlet 42, and the gas flow out of the optical diagnostic system chamber 24 through the apertures 204, 206, and 208 and the valves 210 and 212. The plasma processing system 200 permits the monochromator 38 to be operated at a significantly higher pressure than the plasma process chamber 14 due to the differential pumping of the apertures 204, 206, and 208 and the valves 210 and 212. As a result, the probability of byproducts of the plasma process diffusing through the apertures 204, 206, 208 into the monochromator 38 is reduced. Thus, the probability of the optics being clouded by the plasma byproducts is also reduced.

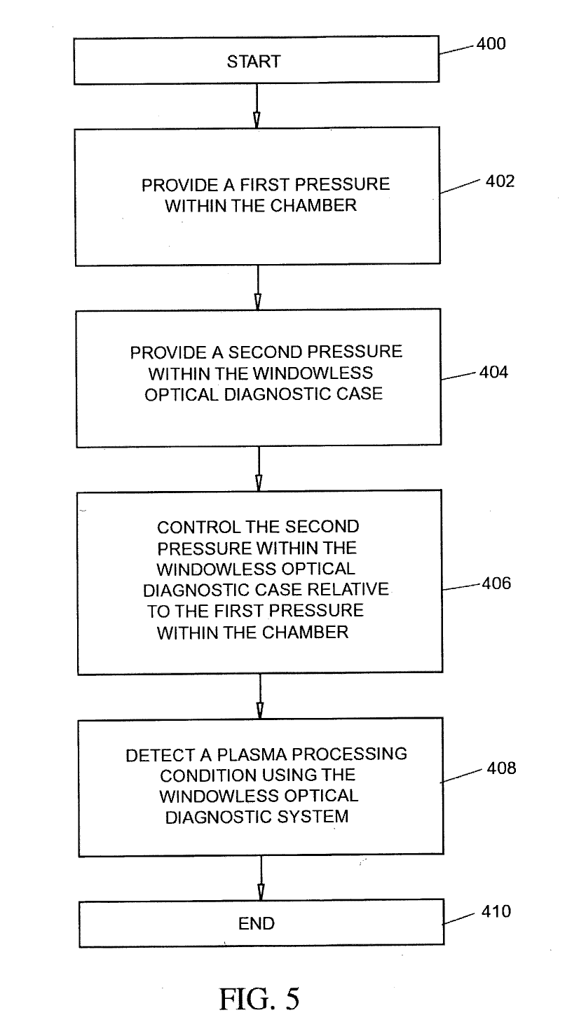

FIG. 5 shows a method in accordance with principles of the invention. The method is for operating a windowless optical diagnostic system in conjunction with a plasma processing system. The plasma processing system has a chamber containing a plasma processing region in which a plasma can be generated during a plasma process and the windowless optical diagnostic system is positioned in a windowless optical diagnostic chamber.

The method starts at 400. At 402, a first pressure within the chamber is provided. At 404, a second pressure within the windowless optical diagnostic chamber is provided. At 406, the second pressure is controlled within the windowless optical diagnostic chamber relative to the first pressure within the chamber. The controlling reduces byproducts of a plasma process that diffuse through the chamber into the windowless optical diagnostic system. The controlling comprises monitoring the first and second pressures and adjusting the second pressure to be less than, substantially equal to or greater than the first pressure. The selection between adjusting the second pressure to be less than, substantially equal to, or greater than the first pressure could depend on the application to which the method is being applied, for example.

At 408, a plasma process condition, such as an endpoint of the plasma process, is detected using the windowless optical diagnostic system. At 410, the method ends.

The method may comprise additional acts, operations or procedures, such as, for example, supplying a purge gas to the windowless optical diagnostic chamber, monitoring the second pressure and adjusting the amount of supplied purge gas to at least partially control the second pressure. Alternatively, the method may comprise monitoring the first and second pressures and adjusting the amount of supplied purge gas to at least partially adjust the second pressure to be less than, substantially equal to or greater than the first pressure.

The plasma processing system and method described above in accordance with the invention may be advantageously used to monitor plasma conditions, as well as determine the endpoint of a plasma etching process, by implementing a windowless optical diagnostic system. The plasma processing system and method eliminate the need to provide an optical diagnostic system having a window subject to coating and clouding to degrade the quality of the data, and which can result in unnecessary costs in yield losses due to incomplete or over etching as well as the costs incurred with the cleaning or replacing of the window.

While the present invention has been particularly shown and described with reference to the preferred embodiments thereof, it will be understood by those skilled in the art that various changes in form and details may be made therein without departing from the spirit and scope of the invention.

What is claimed is:

1. A plasma processing device comprising:
a chamber having an opening and containing a plasma processing region;
a chuck, constructed and arranged to support a substrate within the chamber in the processing region;
a plasma generator in communication with the chamber, the plasma generator being constructed and arranged to generate a plasma during a plasma process in the plasma processing region; and
a windowless optical diagnostic system in communication with the chamber through the opening, the windowless optical diagnostic system being constructed and arranged to detect a plasma process condition.

2. The plasma processing device of claim 1, wherein the plasma generator comprises an upper electrode and a lower electrode spaced from the upper electrode, the upper and lower electrodes being constructed and arranged to generate the plasma therebetween.

3. The plasma processing device of claim 1, wherein the plasma generator is an antenna.

4. The plasma processing device of claim 1, wherein the windowless optical diagnostic system comprises a monochromator constructed and arranged to receive optical transmission from the plasma.

5. The plasma processing device of claim 4, wherein the optical transmission is light.

6. The plasma processing device of claim 1, further comprising an optical diagnostic system chamber in communication with the chamber, wherein the optical diagnostic system chamber is positioned in the chamber.

7. The plasma processing device of claim 6, further comprising a gate valve positioned between the chamber and the optical diagnostic system chamber and being constructed and arranged to substantially isolate the optical diagnostic system chamber from the chamber.

8. The plasma processing device of claim 6, further comprising a first vacuum pump in communication with the chamber and constructed and arranged to control a pressure within the chamber.

9. The plasma processing device of claim 8, further comprising a second vacuum pump in communication with the optical diagnostic system chamber to control a pressure within the optical diagnostic system chamber.

10. The plasma processing device of claim 9, wherein the second vacuum pump is constructed and arranged to maintain a pressure in the optical diagnostic system chamber to be substantially equal or greater than the pressure in the chamber.

11. The plasma processing device of claim 6, further comprising a vacuum pump in communication with the chamber and the optical diagnostic system chamber, the vacuum pump being constructed and arranged to control a pressure within the chamber independent of and relative to a pressure within the optical diagnostic system chamber.

12. The plasma processing device of claim 11, further comprising a vacuum manifold constructed and arranged between the vacuum pump and the chamber and the optical diagnostic chamber to at least partially control a pressure within the optical diagnostic system chamber.

13. The plasma processing device of claim 12, further comprising at least one valve in communication with the vacuum pump and constructed and arranged to at least partially control the pressure within the chamber and the pressure within the optical diagnostic system chamber.

14. The plasma processing device of claim 13, wherein the vacuum pump and the at least one valve are constructed and arranged to at least partially control the pressure in the optical diagnostic system chamber to be substantially equal or greater than the pressure in the chamber.

15. The plasma processing device of claim 6, further comprising a passage interconnecting the chamber and the optical diagnostic chamber, at least one vacuum line coupled to the passage and at least one valve positioned in communication with the vacuum line.

16. The plasma processing device of claim 15, wherein the at least one valve is constructed and arranged to at least partially control a pressure within the optical diagnostic system chamber.

17. The plasma processing device of claim 6, further comprising a differential pump manifold in communication with the chamber opening and the windowless optical diagnostic system.

18. The plasma processing device of claim 17, wherein the differential pump manifold comprises a plurality of apertures, at least one vacuum line between the apertures and at least one valve in communication with the at least one vacuum line.

19. The plasma processing device of claim 17, further comprising a first vacuum pump constructed and arranged to control a pressure within the chamber.

20. The plasma processing device of claim 19, further comprising at least one vacuum line in communication between the differential pump manifold and the first vacuum pump and at least one valve in the at least one vacuum line.

21. The plasma processing device of claim 19, wherein the differential pump manifold is constructed and arranged to at least partially control a pressure in the optical diagnostic system chamber.

22. The plasma processing device of claim 21, wherein the differential pump manifold is constructed and arranged to at least partially control the pressure in the optical diagnostic system chamber such that byproducts of the plasma process that diffuse through the chamber opening into the windowless optical diagnostic system are reduced.

22. A method for operating a windowless optical diagnostic system in conjunction with a plasma processing system having a chamber containing a plasma processing region in which a plasma can be generated during a plasma process, the windowless optical diagnostic system being positioned in a windowless optical diagnostic chamber, the method comprising:
providing a first pressure within the chamber;
providing a second pressure within the windowless optical diagnostic chamber;
controlling the second pressure within the windowless optical diagnostic chamber relative to the first pressure within the chamber; and
optically detecting a plasma process condition.

23. The method of claim 22, wherein the controlling reduces byproducts of a plasma process that diffuse through the chamber into the windowless optical diagnostic system.

24. The method of claim 22, wherein the controlling comprises:
monitoring the first and second pressures; and
adjusting the second pressure in response to the monitoring.

25. The method of claim 24, further comprising:
monitoring the first and second pressures; and
adjusting an amount of supplied purge gas to at least partially adjust the second pressure in response to the monitoring.

26. The method of claim 22, further comprising:
supplying a purge gas to the windowless optical diagnostic chamber;
monitoring the second pressure; and
adjusting the amount of supplied purge gas to at least partially control the second pressure.
